(19) United States
(12) Patent Application Publication
(10) Pub. No.: US 2002/0113304 A1
(43) Pub. Date: Aug. 22, 2002

(54) Dual die package and manufacturing method thereof

(75) Inventors: Jae-Cheon Doh, Chungcheongnam-do (KR); Sang-Ho Ahn, Kyungki-do (KR); In-Ku Kang, Chungcheongnam-do (KR)

Correspondence Address: MARGER JOHNSON & McCOLLOM, P.C., 1030 S.W. Morrison Street, Portland, OR, 97205, US

(73) Assignee: Samsung Electronics Co., Ltd., Suwon-City (KR)

(21) Appl. No.: 10/082,025

(22) Filed: Feb. 20, 2002

(30) Foreign Application Priority Data
Feb. 22, 2001 (KR) 2001-8936

(51) Int. Cl. H01L 21/44

(52) U.S. Cl. 257/686

(57) ABSTRACT

A dual die package with reduced total thickness and a manufacturing method for the dual die package are disclosed. The dual die package includes a first semiconductor chip and a second semiconductor chip. Each chip has an active surface with electrode pads formed thereon. Each chip further includes a lower surface opposite to the active surface. The lower surfaces of said first and said second chip are attached to each other. A plurality of leads are formed adjacent to said first and said second chips. The leads are electrically connected to the electrode pads. A molding body encapsulates the first and second chips and the leads.

### BACKGROUND OF THE INVENTION

1. Field of the Invention

The present invention relates to the field of semiconductor manufacturing, and more particularly to a dual die package (DDP) and a manufacturing method thereof.

2. Description of the Related Art

A multi-chip packaging technique has been applied to meet the ever increasing demand for smaller and thinner packages/chips. With this multi-chip packaging technique, multiple chips can be assembled into a single package. Compared to multiple, single chip packages, the multi-chip package offers reduced size and weight and an increased mounting density.

These multi-chip packages can be classified into two types, i.e. a vertical-stacking type and a parallel-aligning type. The former reduces mounting area, while the latter simplifies the manufacturing process and reduces package thickness. In order to achieve miniaturization and lightweight, the vertical-stacking type has been more commonly used in multi-chip packages. Among this vertical-stacking type, a dual die package (DDP) comprising two semiconductor chips stacked on a lead frame is described below.

FIG. 1 is a cross-sectional view of a conventional dual die package 110.

As shown in FIG. 1, the conventional dual die package 110 comprises a lead frame 120 having a die pad 121 and leads 123, and two semiconductor chips mounted on the die pad 121. The first semiconductor chip 111 and the second semiconductor chip 113 are attached to the upper and the lower surfaces of the die pad 121, respectively. The first and the second chip 111, 113 are electrically connected to the upper and the lower surfaces of the encapsulated ends of the leads 123, i.e., inner leads, by conductive metal wires 127, 128. The first chip 111, the second chip 113, and the conductive metal wires 127, 128 are encapsulated within a epoxy molding compound, thereby forming a molding body 131. Herein, the lower surfaces of the first chip 111 and the second chip 113 are attached to the upper and the lower surface of the die pad 121, respectively. A nonconductive epoxy adhesive or an adhesive tape made of polyimide is used as an adhesive 125, 126 interposed between the first and the second chips 111, 113 and the die pad 121.

The above-described conventional dual die package with two semiconductor chips is lightweight, achieves miniaturization and improves mounting density. However, because this dual die package has a total thickness including the thickness of the lead frame and the height of the wire loops, it is not easy to achieve a thinner profile of the entire package. Moreover, since a series of steps such as wire bonding and molding are carried out after mounting each of the chips on the upper and lower surfaces of the die pad, the already-mounted chips and the conductive metal wires used in the wire bonding may be damaged from mechanical contact with various equipment during package manufacturing steps. In particular, in case of a Lead-On-Chip (LOC) package, failures in the attachment of the chip onto the lead frame may occur. These problems reduce reliability of the package and make it difficult to massproduce.

### SUMMARY OF THE INVENTION

Accordingly, the present invention provides a dual die package (DDP), which reduces total package thickness and prevents damage to chips and electrical connection means.

The dual die package in accordance with one embodiment of the present invention includes a first semiconductor chip and a second semiconductor chip. Each chip has an active surface with electrode pads formed thereon. Each chip further includes a lower surface opposite to the active surface. The lower surfaces of said first and said second chip are attached to each other. A plurality of leads are formed adjacent to said first and said second chips. The leads are electrically connected to the electrode pads. A molding body encapsulates the first and second chips and a portion of the leads.

In another embodiment, the dual die package comprises a first semiconductor chip, a second semiconductor chip, and a plurality of leads formed around the first and second chips. Each chip has an active upper surface with electrode pads formed thereon and a lower surface, and the lower surfaces of the first and the second chip are attached to each other. Opposing inner ends of the leads are separated from each other by a predetermined distance. Further, the dual die package comprises conductive metal wirings for electrically connecting the electrode pads to the leads, and a molding body for molding the first and second chips, conductive metal wirings and inner portions of the leads. An adhesive layer may be interposed between the first chip and the second chip.

Preferably, the first and second chips have electrode pads formed along the edges of the active surfaces, thereby reducing the length of the bonding wire. In order to more effectively accomplish the assembly process, the molding body includes a first molding body for molding the first chip, the conductive metal wirings connected to the first chip and first bonding parts, and a second molding body for molding the second chip, the conductive metal wirings connected to the second chip and second bonding parts.

Further, according to one embodiment, the present invention provides a method for manufacturing dual die packages. A padless lead frame including a plurality of inner leads is provided. A first semiconductor chip is mounted adjacent to the opposing inner leads. The first chip is electrically connected to the inner leads. The first chip and the inner leads are encapsulated. A second semiconductor chip is mounted on the lower surface of the first chip. The second chip is electrically connected to the inner leads. The second chip and the inner leads are encapsulated.

### BRIEF DESCRIPTION OF THE DRAWINGS

These and other objects, features and advantages of the present invention will be readily understood with reference to the following detailed description provided in conjunction with the accompanying drawings, wherein like reference numerals designate like structural elements and in which:

FIG. 1 is a cross-sectional view of a conventional dual die package;

FIG. 2 is a cross-sectional view of a dual die package in accordance with the present invention; and

FIGS. 3a to 3h illustrate the manufacturing process of the dual die package in accordance with the present invention.

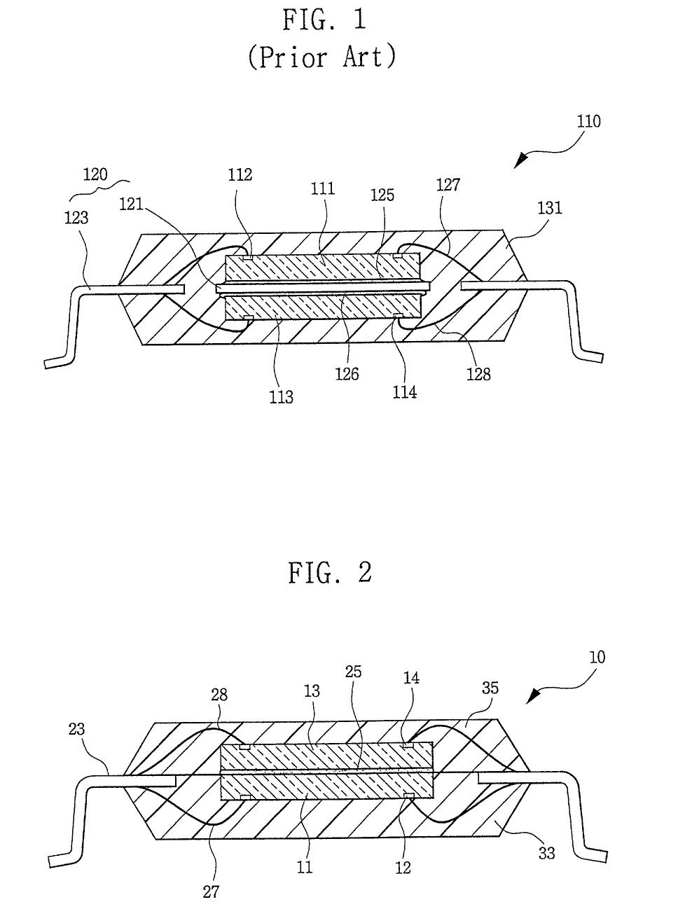

### DETAILED DESCRIPTION OF THE PREFERRED EMBODIMENTS

Preferred embodiments of the present invention will be described below with reference to the accompanying drawings.

FIG. 2 is a cross-sectional view of a dual die package 10 in accordance with the present invention.

As shown in FIG. 2, the dual die package 10 of the present invention comprises a first semiconductor chip 11 and a second semiconductor chip 13. According to this embodiment, there is no die pad between the chips 11, 13 and the lower surfaces of the first chip 11 and the second chip 13 are attached directly to each other, for example, by interposing an adhesive 25 therebetween. However, other methods could also be used to attach the first and the second chips 11, 13 to each other without die pad therebetween.

A plurality of leads 23 are formed around the first chip 11 and the second chip 13. Opposing inner ends of the leads 23 are separated from each other by a predetermined distance. The first chip 11 and the second chip 13 are located between the opposing leads 23. Electrode pads 12 of the first chip 11 and electrode pads 14 of the second chip 13 are electrically connected to the lower and upper surfaces of inner ends of the leads 23, respectively, by electrical connection means such as conductive metal wires 27, 28. The first chip 11 and the conductive metal wires 27 connected to the first chip 11 are encapsulated within a first molding body 33. The second chip 13 and the conductive metal wires 28 connected to the second chip 13 are encapsulated within a second molding body 35. The first molding body 33 and the second molding body 35 are preferably made of a resin compound such as an epoxy molding compound (EMC).

In accordance with the above-described embodiment of the present invention, the dual die package does not require any die pad for mounting a chip on a lead frame. Therefore, compared to the conventional package, the present invention reduces the total thickness of the package by eliminating the die pad and the adhesive coated to the die pad. Further, the present invention has a thickness margin for wire loops, thereby achieving a more stable structure. A process for manufacturing the above-described dual die package is described below.

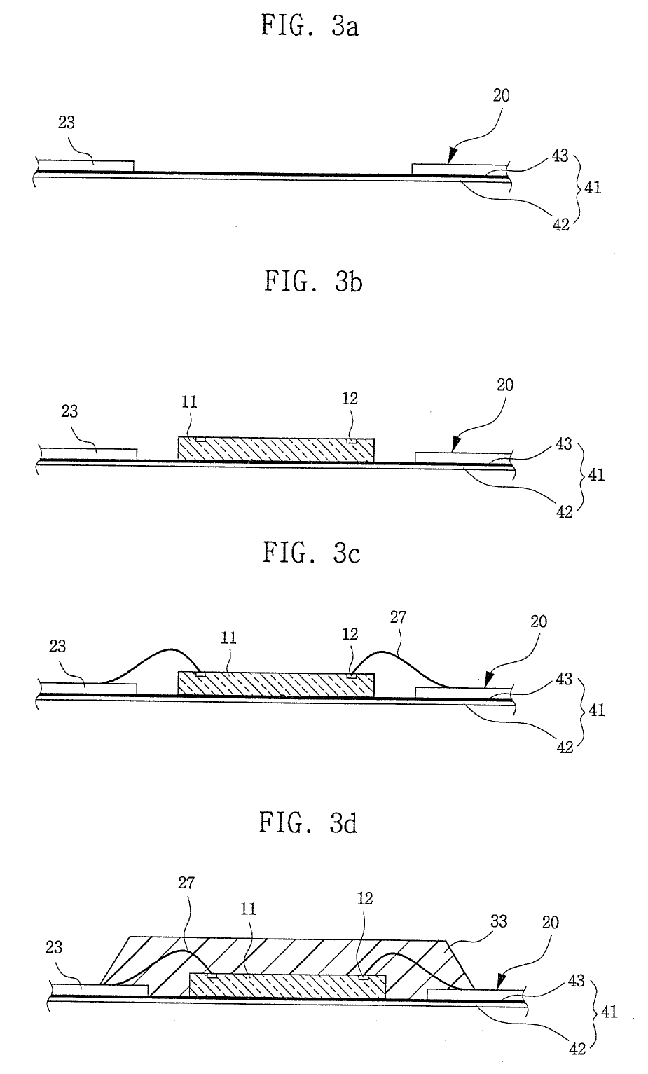

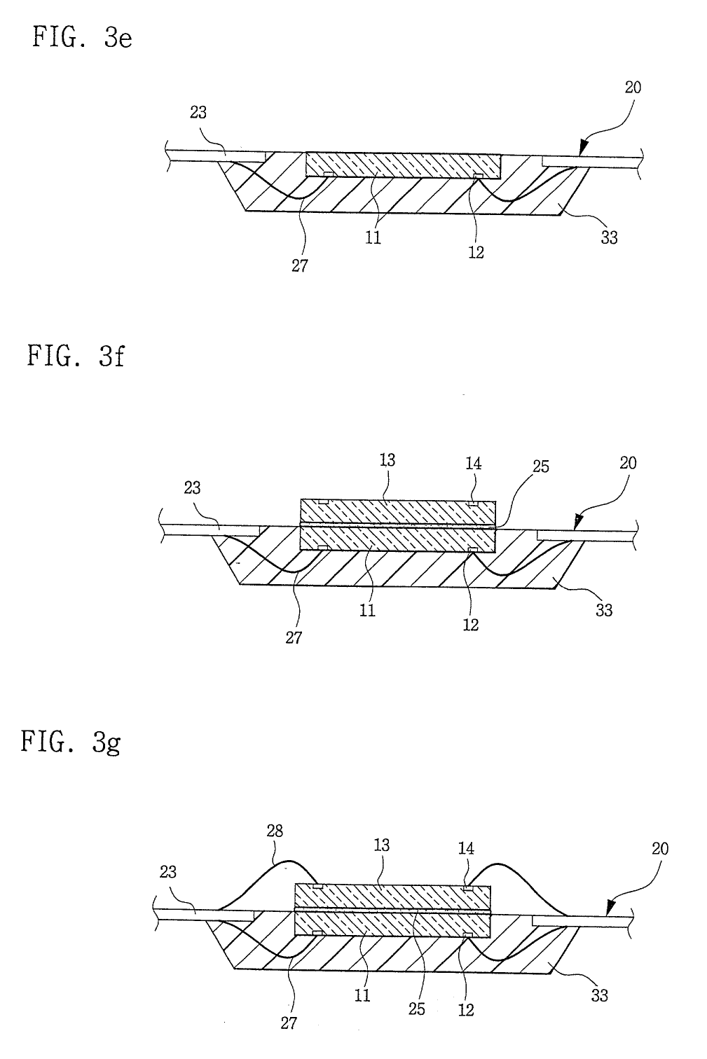

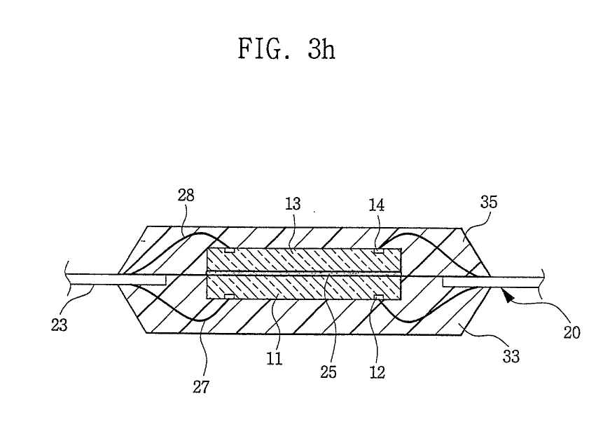

FIGS. 3a to 3h show a manufacturing process of the dual die package in accordance with the present invention.

As shown in FIG. 3a, a padless (without a die pad) lead frame 20 comprising a plurality of leads 23 is prepared. Opposing inner ends of the leads 23 are separated from each other by a predetermined distance. An adhesive tape 41 is attached to a surface of the lead frame 20. The padless lead frame 20 is manufactured by removing a die pad from the conventional lead frame or by using a frame originally manufactured without a die pad. The padless lead frame 20 differs from the conventional LOC lead frame in that it has a window for mounting the semiconductor chip between the opposing leads 23. The tape 41 is made of a metal or a resin. Preferably, in order to easily remove the tape 41 from the padless lead frame 20, the tape 41 includes a polyimide film 42 and a thermosetting adhesive 43 coated on the polyimide film 42.

As shown in FIG. 3b, the first chip 11 is mounted on the tape 41 so that the first chip 11 is disposed between the opposing leads 23. The first chip 11 includes electrode pads 12 formed along the edges of the active upper surface thereof. The lower surface of the first chip 11 is then attached to the tape 41. Instead of the adhesive 43 coated on the polyimide film 42, other adhesives such as Ag epoxy may be used as the attachment means between the first chip 11 and the tape 41.

The first wire bonding is then accomplished as illustrated in FIG. 3C. Each of the electrode pads 12 of the first chip 11 is electrically connected to, such as through wire bonding, to a corresponding one of the leads 23 of the padless lead frame 20 by the conductive metal wires 27. The metal wires 27 can be gold wires.

As shown in FIG. 3d, the first molding is accomplished next. The first chip 11 and the conductive metal wires 27 are encapsulated within a resin molding compound such as epoxy molding resin, thereby forming the first molding body 33. Thus, the first chip 11 and the conductive metal wires 27 are protected from the external environment, to provide reliable electrical operation. At this time, the tape 41 attached to the padless lead frame 20 renders the lead frame 20 easily treatable and prevents overflowing of the molding compound.

Next, the tape 41 is removed from the padless lead frame 20. The tape 41 can be easily removed from the lead frame 20 by hardening the adhesive 43 of the tape 41 at a predetermined temperature. As shown in FIG. 3e, the first chip 11 and the leads 23 are exposed after removing the tape 41.

Referring to FIG. 3f, the second chip 13 is mounted on the lower surface of the first chip 11 such that the second chip 13 is also located between the opposing leads 23. The second chip 13 is preferably the same as the first chip 11, and the lower surface of the second chip 13 is attached to the lower surface of the first chip 11. The chips 11, 13 can be attached, for example, with adhesive 25 such as Ag-epoxy. Because the first chip 11 is fixed into the first molding body 33, the second chip 13 is stably attached to the first chip 11.

The second wire bonding is accomplished as shown in FIG. 3g. Each of the electrode pads 14 of the second chip 13 is electrically connected, e.g., wire bonded, to a corresponding one of the leads 23 of the padless lead frame 20 by the conductive metal wires 28.

The second molding is accomplished, as shown in FIG. 3h. The second chip 13 and the conductive metal wires 28 are encapsulated within a resin molding compound such as epoxy molding resin, thereby forming the second molding body 35. Thus, the second chip 13 and the conductive metal wires 28 connected thereto are protected from the external environment, to provide reliable electrical operation. Although not illustrated herein, outer portions of the leads, i.e., outer leads, which extrude from the first molding body 33 and the second molding body 35, are bent in specific shapes so that the package may be suitably mounted on a substrate. Accordingly, the present invention reduces total package thickness by eliminating a die pad and an adhesive used in attaching chips to the die pad. This reduced thickness provides a thinner profile.

Furthermore, during the manufacturing of a dual die package in accordance with the above-described embodiment of the present invention, the first mounted chip 11 and electrical connection means such as bonding wires 27 can be protected within the molding body 33 from various external impacts during the assembly of the second mounted chip 13. Because the semiconductor chips and the conductive metal bonding wires are protected by the molding body and do not contact various equipment used in the processes, the present invention dual die package prevents the chips and the conductive metal bonding wires from being damaged, thereby improving the reliability of the package.

Although the preferred embodiments of the present invention have been described in detail hereinabove, it should be understood that variations and/or modifications of the basic inventive concepts herein taught, which will be apparent to those skilled in the art, fall within the spirit and scope of the present invention as defined in the appended claims.

What is claimed is:

1. A dual die package (DDP) comprising:
a first semiconductor chip and a second semiconductor chip, each chip having an active surface with electrode pads formed thereon and a lower surface opposite to said active surface, wherein said lower surfaces of said first and said second chip are attached to each other;
a plurality of leads formed adjacent to said first and said second chip, said plurality of leads being electrically connected to said electrode pads; and
a molding body encapsulating said first and second chips and a portion of said leads.

2. The dual die package as claimed in claim 1, wherein the electrode pads are formed along edges of said active surfaces.

3. The dual die package as claimed in claim 1, wherein said molding body comprises:
a first molding body for encapsulating said first chip; and
a second molding body for encapsulating said second chip.

4. The dual die package as claimed in claim 1, wherein an adhesive layer is interposed between said first chip and said second chip.

5. A method of manufacturing dual die packages (DDP), said method comprising:
(a) attaching an adhesive tape to a padless lead frame, said padless lead frame including a plurality of leads, the plurality of leads having opposing inner leads separated from each other;
(b) mounting a first semiconductor chip on said tape between said opposing inner leads;
(c) electrically connecting said first chip to said inner leads;
(d) encapsulating said first chip and said inner leads;
(e) removing said tape from said padless lead frame;
(f) mounting a second semiconductor chip on the lower surface of said first chip between said opposing inner leads;
(g) electrically connecting said second chip to said inner leads; and
(h) encapsulating said second chip and said inner leads.

6. The manufacturing method as claimed in claim 5, wherein said tape is a polyimide film with an adhesive layer formed on one surface thereof.

7. The manufacturing method as claimed in claim 5, wherein said tape is a thermosetting adhesive.

8. A method of manufacturing dual die packages (DDP), said method comprising:
(a) providing a padless lead frame, said padless lead frame including a plurality of inner leads;
(b) mounting a first semiconductor chip adjacent to said opposing inner leads;
(c) electrically connecting said first chip to said inner leads;
(d) encapsulating said first chip and said inner leads;
(e) mounting a second semiconductor chip on the lower surface of said first chip;
(f) electrically connecting said second chip to said inner leads; and
(g) encapsulating said second chip and said inner leads.

9. The method of claim 8, wherein an adhesive layer is interposed between said first chip and said second chip.
